(19) United States
(12) Patent Application Publication
(10) Pub. No.: US 2020/0043856 A1
(43) Pub. Date: Feb. 6, 2020

(54) SEMICONDUCTOR DEVICE AND METHOD OF MANUFACTURING THE SAME

(71) Applicant: RENESAS ELECTRONICS CORPORATION, Tokyo (JP)

(72) Inventor: Kazuyuki OMORI, Tokyo (JP)

(21) Appl. No.: 16/519,527

(22) Filed: Jul. 23, 2019

(30) Foreign Application Priority Data
Aug. 2, 2018 (JP) 2018-145869

(51) Int. Cl. H01L 23/532; H01L 23/522; H01L 21/768

(52) U.S. Cl. CPC H01L 23/53223; H01L 23/5226; H01L 21/76802; H01L 21/76846; H01L 23/53238

(57) ABSTRACT

A semiconductor device having a contact resistance lower than that of a conventional semiconductor device is provided. The semiconductor device comprises a conductive region arranged in or on the semiconductor substrate, an insulating film arranged on the conductive region and provided with a contact hole reaching from the second surface to the conductive region, and a contact plug arranged in contact hole and connected to the conductive region. The contact plug includes a first layer covering a side wall and a bottom wall of the contact hole, and a second layer arranged inside the first layer and located on the third surface of the contact plug in the contact hole. Materials constituting the first layer include aluminum and cobalt. The material constituting the second layer includes at least one of aluminum and copper and does not include cobalt.

### CROSS-REFERENCE TO RELATED APPLICATIONS

The disclosure of Japanese Patent Application No.2018-145869 filed on Aug. 2, 2018 including the specification, drawings and abstract is incorporated herein by reference in its entirety.

### BACKGROUND

The present invention relates to semiconductor device and method of manufacturing the same.

Conventionally, there has been known a semiconductor device provided with a conductive region such as an impurity region or a gate electrode arranged in a semiconductor substrate, an insulating film arranged on the semiconductor substrate, a wiring arranged on the insulating film, and a contact plug arranged in a contact hole penetrating the insulating film to electrically connect the conductive region and the wiring. A typical contact plug is made of tungsten (W) and is formed by Chemical Vapor Deposition (CVD).

Recently, miniaturization of circuit patterns of semiconductor device has progressed. As a result, an aspect ratio of the contact hole is increased, and an influence of contact resistance on device performance is increased. Therefore, the semiconductor device has been proposed in which the main constituent material of the contact plug is changed to aluminum (Al), which has a lower resistivity than tungsten (W). Such a semiconductor device is disclosed, for example, in Japanese Patent Laid-Open No. 2009-26989 (Patent Document 1).

The contact plug described in Patent Document 1 is configured as a laminate of an Al film as a first-stage contact plug and a refractory metal film as a second-stage contact plug. The Al film is formed by Physical Vapor Deposition (PVD) or CVD so as to fill the entire contact hole. The refractory metal film is formed in a recess formed by etching an upper portion of the Al film. The contact hole described in Patent Document 1 has a diameter of 70 nm and a depth of 300 nm.

Conventionally, in a trench gate type semiconductor device, there has been known a technique of forming a gate electrode mainly made of Aluminum (Al) in a trench by reflowing Al. In this technique, in order to facilitate filling of Al into the trench, a film made of titanium (Ti) or cobalt (Co) is formed on the inner circumferential surface of the trench before reflowing Al. It should be noted that the aspect ratio of a conventional general trench gate is less than the aspect ratio of the contact hole.

In the reflow method of Al using a Co film, Co diffuses in the Al film at the time of heating for reflow and aggregates on a surface of the Al film. Therefore, when the Co film and the Al film formed on the insulating film are polished and removed by Chemical Mechanical Polishing (CMP), Co is corroded by the slurry used for CMP. In order to suppress this, a thickness of the Co film is made as thin as possible by the Al reflow method in the trench gate type semiconductor device.

### SUMMARY

However, an Al contact plug mainly composed of Al has not been used for contact plug embedded in a contact hole having an aspect ratio higher than that of the contact hole described in Patent Document 1. This is because it is difficult to sufficiently reduce the contact resistance with the Al contact plug formed in the contact hole having a high aspect ratio by conventional PVD method, CVD method, and reflow method.

For example, inventors have confirmed that when a Ti film is formed on the inner circumferential surface of the contact hole having the aspect ratio of 5 or more and then Al is reflowed based on a reflow method used in conventional trench gate formation, an upper portion of the contact hole is closed by Al and a relatively large voids are formed below the closed portion. Furthermore, the inventors have confirmed that voids are also formed in the contact hole by conventional reflow method using a Co film instead of the Ti film.

Other objects and novel features will become apparent from the description of this specification and the accompanying drawings.

The semiconductor device according to this embodiment comprises a conductive region arranged in or on the semiconductor substrate, an insulating film arranged on the conductive region and provided with a contact hole reaching from the upper surface to the conductive region, and a plug conductive layer arranged in the contact hole and connected to the conductive region. The plug conductive layer includes a first layer covering a side wall and a bottom wall of the contact hole, and a second layer arranged inside the first layer and located upper surface the plug conductive layer in the contact hole. Materials constituting the first layer include aluminum and cobalt. The material constituting the second layer includes at least one of aluminum and copper and does not include cobalt.

### BRIEF DESCRIPTION OF THE DRAWINGS

FIG. 1 is a cross-sectional view of a semiconductor device according to first embodiment.

FIG. 2 is an plan view of a contact plug and an insulating film of the semiconductor device shown in FIG. 1.

FIG. 3 is a cross-sectional view illustrating one step of the manufacturing method of the semiconductor device according to first embodiment.

FIG. 4 is a cross-sectional view illustrating one step performed after the step shown in FIG. 3 in the manufacturing method of the semiconductor device according to first embodiment.

FIG. 5 is a cross-sectional view illustrating one step performed after the step shown in FIG. 4 in the manufacturing method of the semiconductor device according to first embodiment.

FIG. 6 is a cross-sectional view illustrating one step performed after the step shown in FIG. 5 in the manufacturing method of the semiconductor device according to first embodiment.

FIG. 7 is a cross-sectional view illustrating one step performed after the step shown in FIG. 6 in the manufacturing method of the semiconductor device according to first embodiment.

FIG. 8 is a cross-sectional view illustrating one step performed after the step illustrated in FIG. 7 in the manufacturing method of the semiconductor device according to first embodiment.

FIG. 9 is a cross-sectional view illustrating one step performed after the step illustrated in FIG. 8 in the manufacturing method of the semiconductor device according to first embodiment.

FIG. 10 is the cross-sectional view of a semiconductor device according to second embodiment.

FIG. 11 is the cross-sectional view of a semiconductor device according to third embodiment.

FIG. 12 is the cross-sectional view of a semiconductor device according to fifth embodiment.

FIG. 13 is cross-sectional view illustrating one step of the manufacturing method of the semiconductor device according to fifth embodiment.

FIG. 14 is a cross-sectional view illustrating one step performed after the step illustrated in FIG. 13 in the manufacturing method of the semiconductor device according to fifth embodiment.

FIG. 15 is a cross-sectional view illustrating a modification of the semiconductor device according to first embodiment.

FIG. 16 is a cross-sectional view illustrating a modification of the semiconductor device according to second embodiment.

FIG. 17 is a cross-sectional view illustrating a modification of the semiconductor device according to third embodiment.

FIG. 18 is a cross-sectional view illustrating a modification of the semiconductor device according to fifth embodiment.

### DETAILED DESCRIPTION

Hereinafter, embodiments will be described with reference to the drawings. It should be noted that the same or corresponding parts in the following drawings are followed by the same reference numerals, and the explanation thereof will not be repeated.

### First Embodiment

<Configuration of Semiconductor Device>

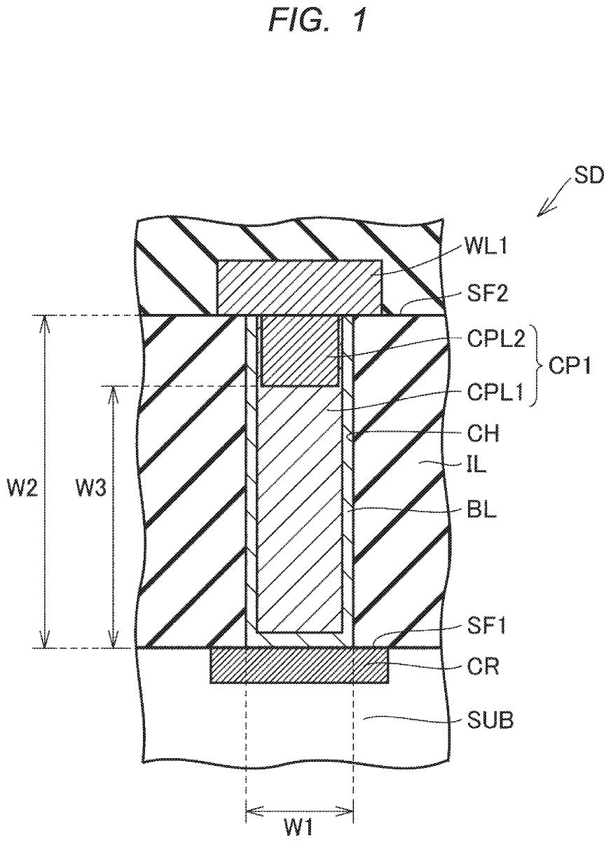

As shown in FIG. 1, the semiconductor device SD according to first embodiment includes a semiconductor substrate SUB, a conductive region CR as a conductive portion, an insulating film IL, a barrier layer BL, a contact plug CP1 as a plug conductive layer, and a wiring WL1.

The semiconductor substrate SUB has a first surface SF1. For example, single crystal silicon (Si) is used for the semiconductor substrate SUB. However, the materials used for the semiconductor substrate SUB is not limited to this. For example, silicon carbide or the like may be used for the semiconductor substrate SUB.

The conductive region CR is formed in the semiconductor substrate SUB. The conductive region CR is arranged in the first surface SF1. The conductive region CR is, for example, an impurity region having a first conductivity type. In case of the semiconductor device SD is Metal Oxide Semiconductor Field Effect Transistor (MOSFET), the conductive region CR is configured as, for example, a source region or a drain region.

The insulating film IL is arranged on the first surface SF1 of the semiconductor substrate SUB. The insulating film IL has an upper surface arranged on the first surface SF1, hereinafter referred to as a second surface SF2. A thickness of the insulating film IL is, for example, 100 nm or more and 2000 nm or less. The material of the insulating film IL may be any material having an electrically insulating property, and includes, for example, SiO2. A contact hole CH is formed in the insulating film IL.

The contact hole CH is an opening on the second surface SF2 and is a through hole formed so as to reach the conductive region CR from the second surface SF2. A side wall of the contact hole CH is formed of the insulating film IL. A bottom wall of the contact hole CH is formed of the conductive region CR. An aspect ratio W2/W1 defined by the depth W2 of the contact hole CH with respect to the opening dimension W1 of the contact hole CH in the second surface SF2 of the insulating film IL is 5 or more. That is, the aspect ratio of the contact hole CH exceeds, for example, the aspect ratio of the trench structures of the gate in a conventional trench gate type MOSFET. The opening dimension W1 of the contact hole CH is the narrowest width of the contact hole CH when the second surface SF2 is viewed in plan view. For example, when the planar shape of the contact hole CH, when the second surface SF2 is seen in plan view, is a rectangular shape or an elliptical shape, the opening dimension W1 is the length of the short side or the short axis of the contact hole CH.

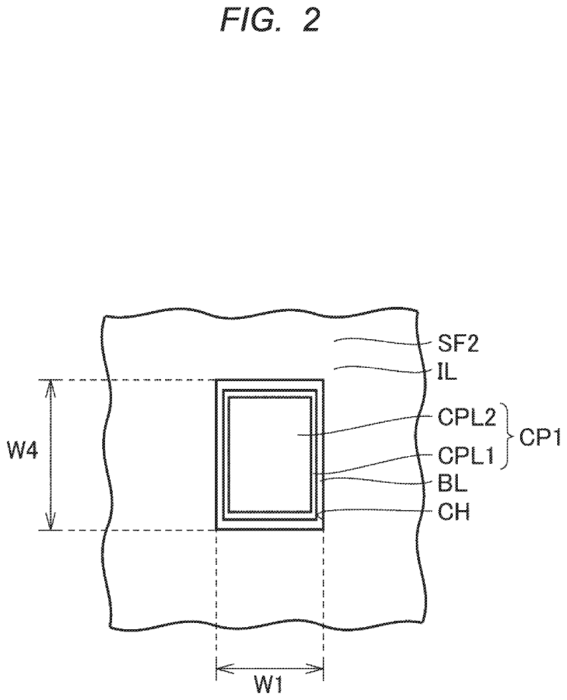

Further, as shown in FIG. 2, when the length of the long side or the long axis of the contact hole CH when the second surface SF2 is seen in plan view is defined as an opening dimension W4, a ratio of the opening dimension W4 to the opening dimension W1 of the contact hole CH is, for example, 3 or less. That is, the opening dimension of the contact hole CH in the second surface SF2 is shorter than, for example, a length of a long side of the trench gate in plan view in the conventional trench gate type MOSFET. The planar shape of the contact hole CH may be any shape, and may be a square shape, a circular shape, or the like.

The barrier layer BL is arranged in the contact hole CH. The barrier layer BL is arranged so as to be in contact with the side wall and the bottom wall of the contact hole CH. The barrier layer BL has an outer circumferential surface which is in contact with the side wall and the bottom wall of the contact hole CH, and an inner circumferential surface which is arranged on the opposite side to the outer circumferential surface and faces inward in the contact hole CH. The inner circumferential surface of the barrier layer BL is in contact with the outer peripheral surface of the contact plug CP1. The barrier layer BL is contact to and electrically connected to the conductive region CR and the contact plug CP1. The barrier layer BL is configured, for example, as a stacked body in which plurality of films are stacked. The barrier layer BL is provided, for example, so as to prevent hydrogen from entering the contact plug CP1 from the insulating film IL. For example, when tungsten (W) is formed using tungsten fluoride (WF6) by CVD method, the barrier layer BL is not required to have a barrier performance for preventing so-called fluorine attack, which is given to the semiconductor substrate SUB and the insulating film IL when the tungsten (W) is formed by CVD method. The barrier layer BL is, for example, a laminate of a titanium (Ti) film having the outer circumferential surface of the barrier layer BL and a titanium nitride (TiN) film having the inner circumferential surface of the barrier layer BL. The thickness of the barrier layer BL, that is, the distance between the outer circumferential surface and the inner circumferential surface of the barrier layer BL is, for example, 2 nm or more and 15 nm or less.

The contact plug CP1 is arranged in the contact hole CH of the insulating film IL. The contact plug CP1 is arranged on the inner circumferential surface of the contact hole CH covered with the barrier layer BL. The contact plug CP1 is contact to and electrically connected to the conductive region CR through the barrier layer BL. Further, the contact plug CP1 is electrically connected to the wiring WL1. The contact plug CP1 is densely arranged in the contact hole CH. The ratio of the maximum width of the contact plug CP1 in the direction perpendicular to the first surface SF1 to the maximum width of the contact plug CP1 in the direction along the first surface SF1 along the first surface SF1 is 5 or more.

The contact plug CP1 have an upper surface arranged on the first surface SF1, hereinafter referred to as a third surface SF3. The third surface SF3 is provided, for example, so as to be continuous with the second surface SF2 of the insulating film IL. The second surface SF2 and the third surface SF3 are simultaneously formed by CMP process in the manufacturing method of the semiconductor device SD. The insulating film IL, the barrier layer BL, and the contact plug CP1 are polished by the same CMP process. The third surface SF3 of the contact plug CP1 is in contact with the wiring WL1.

The contact plug CP1 include a first layer CPL1 and a second layer CPL2. The first layer CPL1 is provided so as to cover the side wall and the bottom wall of the contact hole CH. The second layer CPL2 is arranged inside the first layer CPL1 in the contact hole CH and is located on the third surface SF3 of the contact plug CP1. The second layer CPL2 is in contact with the first layer CPL1.

Materials constituting the first layer CPL1 include aluminum (Al) and cobalt (Co). The first layer CPL1 includes an alloyed AlCo of Al and Co.

Materials constituting the second layer CPL2 does not contain Co. That is, the Co concentration of the second layer CPL2 is less than the detectable limit of the Energy Dispersive X-ray spectrometry (EDX) analysis. The material constituting the second layer CPL2 is a material which is able to polish by CMP and is hardly electrochemically corroded by CMP as compared with Co. Preferably, the resistivity of the materials constituting the second layer CPL2 is less than the resistivity of tungsten (W), specifically less than 5.6×10−8 Ω·m. Materials constituting the second layer CPL2 include, for example, Al. Al is a material which is able to polish by CMP and is hardly electrochemically corroded by CMP as compared with Co. Furthermore, the resistivity of Al is less than the resistivity of W, specifically less than 5.6×10−8 Ω·m. The second layer CPL2 may include alloys of aluminum.

As shown in FIG. 2, in addition to the second layer CPL2, the first layer CPL1 is arranged in the third surface SF3 of the contact plug CP1. The second layer CPL2 is arranged in a central region of the third surface SF3. The first layer CPL1 is arranged in an outer peripheral region of the third surface SF3 surrounding the central region. The occupied area of the second layer CPL2 exceeds the occupied area of the first layer CPL1. In FIG. 2, the illustration of the wiring WL1 is omitted.

A width of the second layer CPL2 in the direction along the first surface SF1 is less than a width of the first layer CPL1 in the direction along the first surface SF1. a width of the contact plug CP1 in the direction along the first surface SF1 is equal to the width of the first layer CPL1 in the direction along the first surface SF1. The third width W3 of the first layer CPL1 perpendicular to the first surface SF1 is 40 nm or more. The third width W3 of the first layer CPL1 in the direction perpendicular to the first surface SF1 exceeds, for example, the width of the second layer CPL2 in the direction perpendicular to the first surface SF1.

The wiring WL1 is arranged on the third surface SF3 of the contact plug CP1 and the second surface SF2 of the insulating film IL. The materials constituting the wiring WL1 include, for example, at least one of Al and Copper (Cu), and include, for example, CuAl.

<Manufacturing Method of Semiconductor Device>

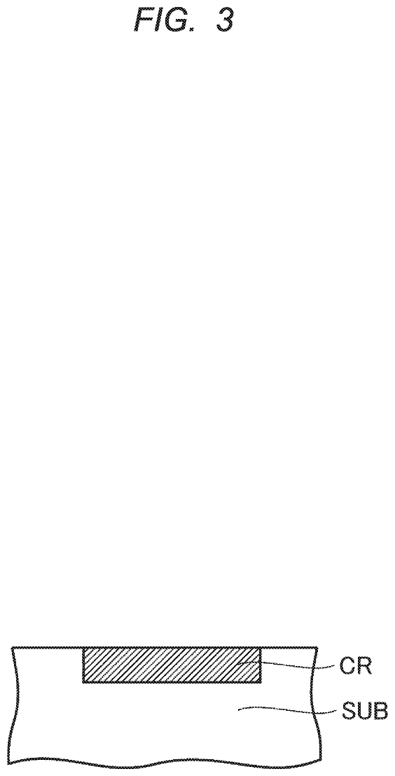

The semiconductor device SD according to first embodiment is manufactured by sequentially executing the steps shown in FIGS. 3 to 9.

First, as shown in FIG. 3, the semiconductor substrate SUB having the first surface SF1 and the conductive region CR arranged in the first surface SF1 is prepared.

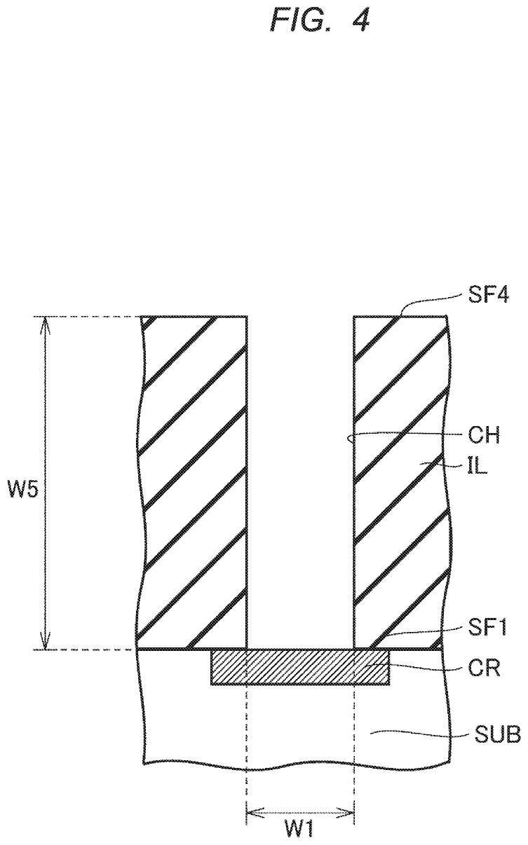

Next, as shown in FIG. 4, an insulating film is formed on the first surface SF1. Specifically, first, the insulating film IL is formed on the first surface SF1. The insulating film IL is formed by, for example, CVD. Next, a masking film having an opening is formed on the fourth surface SF4 of the insulating film IL. The mask film is formed by, for example, photolithography. The opening of the masking film is arranged so as to overlap the conductive region CR in direction perpendicular to the first surface SF1. Next, the contact hole CH reaching from the fourth surface SF4 to the conductive region CR is formed by anisotropic etching using the masking film. Next, the mask film is removed. In this manner, the insulating film IL shown in FIG. 4 is formed.

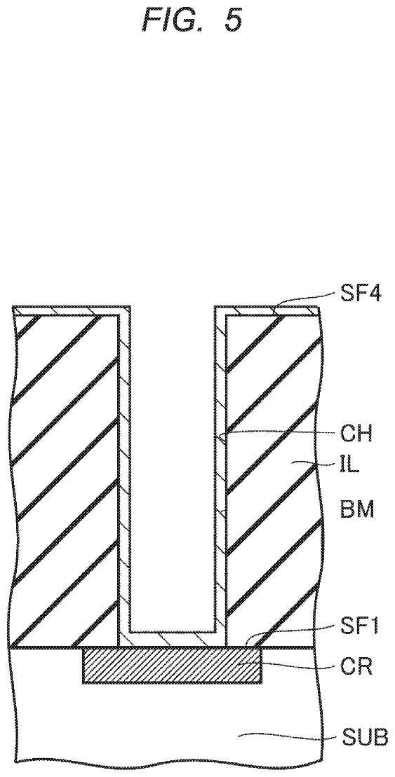

Next, as shown in FIG. 5, the barrier film BM is formed in contact with the side wall and the bottom wall in the contact hole CH. In case of the barrier film BM is formed as a laminate of a Ti film and a TiN film, the Ti film is formed, for example, by PVD, and the TiN film is formed, for example, by Metal Organic Chemical Vapor Deposition (MOCVD).

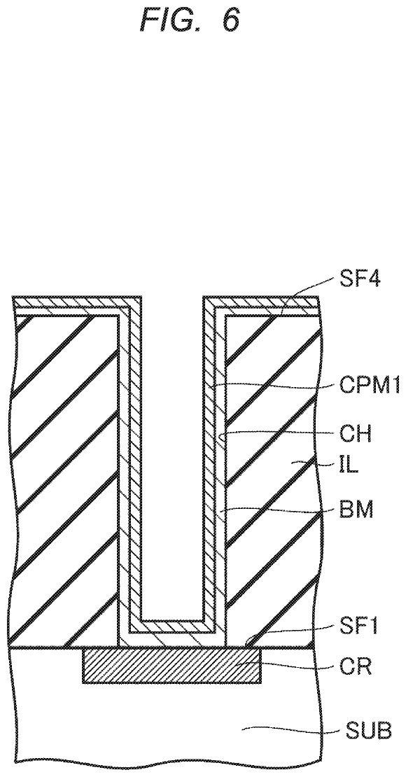

Next, as shown in FIGS. 6 to 9, the contact plug CP1 is contact to and electrically connected to the conductive region CR is formed in the contact hole CH of the insulating film IL.

Specifically, first, as shown in FIG. 6, a first film CPM1 containing Co is formed on the side wall and the bottom wall of the contact hole CH. The first film CPM1 is also formed, for example, on the fourth surface SF4 of the insulating film IL. The first film CPM1 includes Co. That is, the first film CPM1 is formed so that Al easily spreads into the contact hole CH. The first film CPM1 is formed, for example, by CVD. A thickness of the first film CPM1 is 3 nm or more.

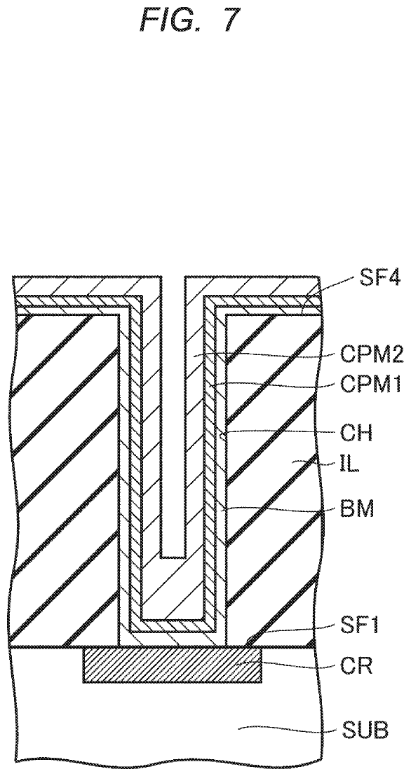

Next, as shown in FIG. 7, a second film CPM2 containing Al is formed on the first film CPM1. The second film CPM2 is formed, for example, on the entire surface of the first surface SF1, that is, on the side wall and the bottom wall of the contact hole CH, and on the fourth surface SF4 of the insulating film IL. The second film CPM2 is formed, for example, by PVD. Preferably, the thickness of the second film CPM2 is set so that the distance between the upper surface of the second film CPM2 and the first surface SF1 after reflowing in the subsequent step is 40 nm or more.

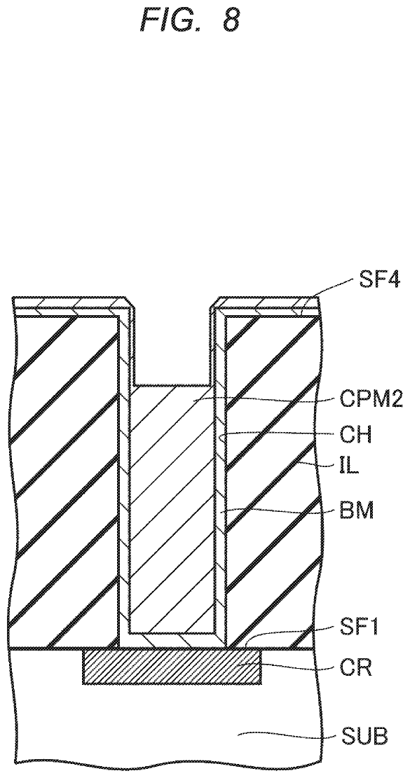

Next, as shown in FIG. 8, the second film CPM2 is reflowed into the contact hole CH by heating the semiconductor substrate SUB to a temperature of 350° C. or more and 450° C. or less. As a result, the second film CPM2 arranged on the side wall of the contact hole CH and on the fourth surface SF4 of the insulating film IL is reflowed and embedded in the region which is located on the wall bottom side of the contact hole CH and is not arranged the second film CPM2 before reflowing. By this reflow treatment, Co in the first film CPM1 diffuses into the second film CPM2. As a result, the first film CPM1 and the second film CPM2 are reconstituted into one film containing an alloyed AlCo of Al and Co by the reflow. In this specification, for convenience of description, a film containing the alloy formed after reflowing is referred to as a reflowed second film. For example, Co is aggregated on the surface of the reflowed second film.

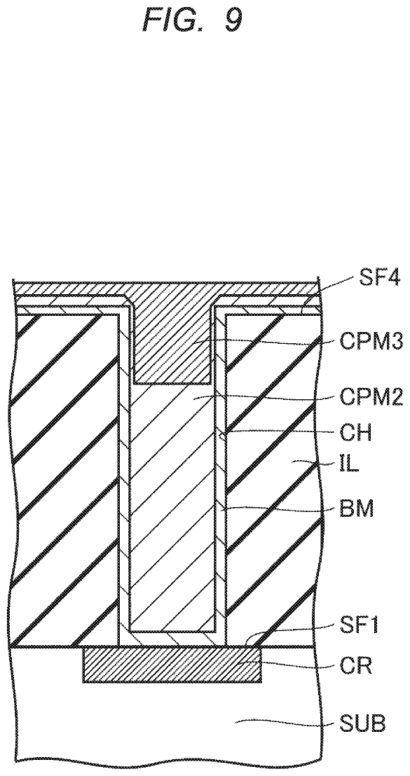

Next, as shown in FIG. 9, a third film CPM3 containing at least one of Al and Cu and containing no Co is formed on the reflowed second film. The third film CPM3 is formed by a method other than a reflow method, for example, a PVD method. In the step of forming the third film CPM3, the semiconductor substrate SUB, the insulating film IL, the reflowed second film, and the third film CPM3 are not heated to 350° C. or more. As a result, the barrier film BM, the reflowed second film, and the third film CPM3 are densely arranged in the contact hole CH. On the fourth surface SF4 of the insulating film IL, the barrier film BM, the reflowed second film, and the third film CPM3 are stacked in this order.

Next, the barrier film BM arranged on the fourth surface SF4 of the insulating film IL, that is, on the fourth surface SF4 of the insulating film IL, the reflowed second film, and the third film CPM3 are polished by CMP. The polishing is performed until at least the fourth surface SF4 of the insulating film IL is exposed. In this process, for example, in addition to the barrier film BM arranged on the fourth surface SF4, the reflowed second film, and the third film CPM3, the upper area of the insulating film IL located on the fourth surface SF4 is also polished. As a result, the contact plug CP1 are formed from the second film CPM2 and the third film CPM3 remaining in the contact hole CH. Specifically, the first layer CPL1 is formed from the second film CPM2, and the second layer CPL2 is formed from the third film CPM3. Further, the barrier layer BL is formed from the barrier film BM remaining in the contact hole CH. The second surface SF2 as a new upper surface is formed on the insulating film.

<Effect of Semiconductor Device>

Hereinafter, the effect of the semiconductor device SD according to the embodiment will be described based on the comparison with the semiconductor device and the like described in the Patent Document 1.

The contact plug described in Patent Document 1 contains Al, but does not contain Co, and Al is not reflowed after being formed by the PVD method. It is difficult to embedded Al into the contact hole CH having the aspect ratio of 5 or more without a gap only by the PVD method. Therefore, in case of the contact plug described in Patent Document 1 is applied to the contact plug formed in the contact hole CH having the aspect ratio of 5 or more, there is a problem that the contact resistance increases.

Further, as described above, the inventors have confirmed that when the Ti film is formed on the inner circumferential surface of the contact hole having the aspect ratio of 5 or more and then Al is reflowed based on the reflow method used in the conventional trench gate formation, the upper portion of the contact hole is closed by Al, and a relatively large voids are formed below the closed portion.

Further, the inventors have confirmed that voids are formed in the contact hole even when a Co film is used instead of a Ti film based on a reflow method used for forming a trench gate in the related art. In the conventional reflow method using the Co film, the thickness of the Co film is limited to, for example, about 1.6 nm or less in order to reduce the amount of diffusion of Co into Al and suppress corrosion of Co by CMP. the inventors have confirmed that even when Al is reflowed after forming a relatively thin Co film on the inner circumferential surface of the contact hole having an aspect ratio of 5 or more, the upper portion of the contact hole is closed by Al, and a relatively large voids are formed below the closed portion. Incidentally, when the thickness of the Co film is increased, the amount of diffusion of Co into Al increases, the amount of corrosion of Co by CMP increases, and voids are formed in the contact plug.

On the other hand, the contact plug CP1 of the semiconductor device SD include Al and Co, and include a first layer CPL1 that covers the side walls and the bottoms of the contact hole CH. As described above, the first layer CPL1 is formed by forming the first film CPM1 containing Co so as to cover the side wall and the bottom wall of the contact hole CH, and then forming the second film CPM2 containing Al on the first film CPM1 and reflowing the Al. As a result, the first layer CPL1 is densely arranged without a gap even in the lower region where it is particularly difficult to form an Al film without a gap only by PVD or the like in the contact hole CH having the aspect ratio of 5 or more. Therefore, the contact resistances of the contact plug CP1 of the semiconductor device SD is reduced as compared with those of the semiconductor device disclosed in the Patent Document 1.

Further, the first layer CPL1 includes an AlCo formed by diffusing Co in the first film CPM1 into Al in the second film CPM2 in the manufacturing method of the semiconductor device SD. Therefore, the contact plug CP1 including the first layer CPL1 has higher resistance to electromigration (EM) and stress migration (SM) than the contact plug not including AlCo.

Further, in the semiconductor device SD, the contact plug CP1 further include the second layer CPL2 that does not include Co, and the second layer CPL2 is located on the third surface SF3 of the semiconductor device SD. As described above, the contact plug CP1 is formed by depositing the third film CPM3 containing no Co on the reflowed second film and polishing it by CMP. Therefore, the contact plug CP1 is hardly corroded during polishing by CMP as compared with a contact plug which is polished by CMP without forming the third film CPM3 after reflowing Al on the Co film, that is, a contact plug which is entirely made of AlCo during polishing by CMP. As a result, voids are less likely to be formed in the contact plug CP1, and the contact resistance of the semiconductor device SD is reduced as compared with the contact resistance of the semiconductor device including the contact plug made entirely of AlCo at the time of polishing by CMP.

Furthermore, even if the Co concentration in the first layer CPL1 of the contact plug CP1 is set higher than the Co concentration of the trench gates formed by the Al reflow method using the conventional Co film, the corrosion by CMP is suppressed. That is, the first film CPM1 can be made thicker than the Co film whose thickness is limited in order to suppress corrosion of Co by CMP in the conventional reflow method using the Co film. The inventors confirmed that Al can be densely embedded in the contact hole CH having the aspect ratio of 5 or more by reflowing Al on the first film CPM1 having a thickness of 3 nm or more.

The resistivity of Al contained in the first layer CPL1 is 2.8×10−8 Ω·m. Furthermore, the resistivity of the materials constituting the second layer CPL2 is less than 5.6×10−8 Ω·m, that is, less than the resistivity of Tungsten (W). Therefore, the contact resistance of the contact plug CP1 is lower than the contact resistance of a conventional contact plug made of Tungsten (W).

In the third surface SF3 of the contact plug CP1, the second layer CPL2 is arranged in a central region, and the first layer CPL1 is arranged in an outer peripheral region surrounding the central region. In the third surface SF3, the occupied area of the second layer CPL2 exceeds the occupied area of the first layer CPL1. Therefore, the contact plug CP1 of the semiconductor device SD is formed by reflowing Al using the Co film, it is less likely to be corroded at the time of polishing by CMP, and it is less likely to form voids further, as compared with a contact plug made entirely of AlCo at the time of polishing by CMP. Therefore, the contact resistance of the semiconductor device SD including the contact plug CP1 is reduced as compared with the contact resistance of the semiconductor device including the contact plug made entirely of AlCo at the time of polishing by CMP.

In the semiconductor device SD, the aspect ratio of the contact hole CH in the second surface SF2 of the insulating film IL is 5 or more. As described above, the aspect ratio of the contact hole CH exceeds, for example, the aspect ratio of the trench structures of the gate in the conventional trench gate type MOSFET. When a metal material is embedded in a concave portion such as a contact hole and a trench by a reflow method, it becomes more difficult to suppress the generation of voids in the concave portion as the aspect ratio of the concave portion increases. The conventional Al reflow method cannot suppress the generation of voids in the contact hole having the aspect ratio of 5 or more.

Further, as described above, in the planar shape of the contact hole CH, the ratio of the width in the second direction to the width in the first direction is, for example, 3 or less. That is, the opening dimension of the contact hole CH in the second surface SF2 is shorter than, for example, the length of the long side of the trench gate in plan view in the conventional trench gate type MOSFET. When the metal material is embedded in the concave portion such as the contact hole and the trench by the reflow method, it becomes more difficult to suppress the generation of voids in the concave portion as the above ratio of the contact hole CH becomes higher. The conventional Al reflow method cannot suppress the generation of voids in the contact hole having the above ratio of 3 or less.

On the other hand, in the manufacturing method of the semiconductor device SD, by making the thickness of the first film CPM1 thicker than the thickness of the Co film used in the conventional Al reflow method, it is realized that the contact plug CP1 densely arranged in the contact hole CH having the aspect ratio of 5 or more and the above ratio of 3 or less. As described above, in the semiconductor device SD, the corrosion of the contact plug CP1 is prevented by the second layer CPL2 at the time of polishing by CMP. Therefore, in the manufacturing method of the semiconductor device SD, the thickness of the first film CPM1 is not particularly limited by the viewpoint of preventing the corrosion of the contact plug CP1 by CMP, and can be set based on the viewpoint of suppressing the generation of voids. As a result, the semiconductor device SD can include contact plug CP1 densely arranged in the contact hole CH having the above mentioned high aspect ratio and the above mentioned ratio of 3 or less.

The width of the first layer CPL1 in the direction perpendicular to the third surface SF3 of the insulating film IL exceeds the width of the second layer CPL2 in the direction. That is, the first layer CPL1 formed by the reflow method occupies more than half of the depth below the contact hole CH, and the second layer CPL2 formed by the deposition method other than the reflow occupies less than half of the depth above the contact hole CH. In this case, even if the aspect ratio of the contact hole CH is 5 or more, the depth of the area in which the third film CPM3 is to be formed in the contact hole CH after the second film CPM2 is reflowed is relatively shallow. Therefore, the generation of voids is suppressed also in the third film CPM3 formed by a film forming method other than the reflow method. As a result, generation of voids is suppressed in the second layer CPL2 formed from the third film CPM3.

### Second Embodiment

A semiconductor device SD2 according to second embodiment has basically the same configuration as the semiconductor device SD according to first embodiment. The semiconductor device SD2 differs from the semiconductor device SD in that the semiconductor device SD2 includes a contact plug CP2 not including the second layer CPL2 instead of the contact plug CP1 including the second layer CPL2.

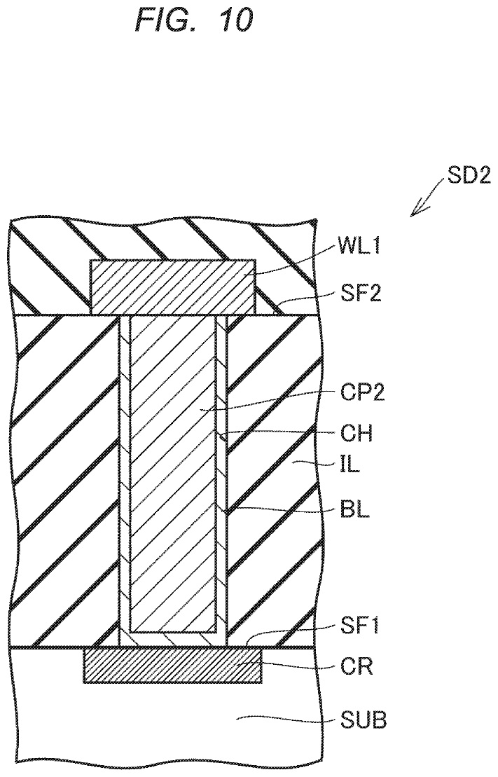

As shown in FIG. 10, the contact plug CP2 of the semiconductor device SD2 do not include the second layer CPL2 shown in FIG. 1. Materials constituting the contact plug CP2 include Al and Co. Co is aggregated on the third surface SF3 of the contact plug CP2. The contact plug CP2 is densely arranged in the contact hole CH.

The manufacturing method of the semiconductor device SD2 basically has the same configuration as the manufacturing method of the semiconductor device SD according to first embodiment, but differs from the manufacturing method of the semiconductor device SD according to first embodiment in that it further includes a step of heating the contact plug CP1 after CMP polishing to diffuse Co into the contact plug CP1. That is, in the manufacturing method of the semiconductor device SD2, first, the semiconductor device SD is manufactured, and then Co in the first layer CPL1 of the contact plug CP1 of the semiconductor device SD is diffused into the second layer CPL2. As a result, the semiconductor device SD2 is manufactured.

Since such the semiconductor device SD2 also has a configuration equivalent to that of the semiconductor device SD at the time of polishing by CMP, so that the same effect as the semiconductor device SD can be obtained.

Further, since the whole of the contact plug CP2 of the semiconductor device SD2 includes AlCo, the contact plug CP1 has higher tolerance to electro migration (EM) and stress migration (SM) as compared with the contact plug CP1 including the second layer CPL2 not containing AlCo.

### Third Embodiment

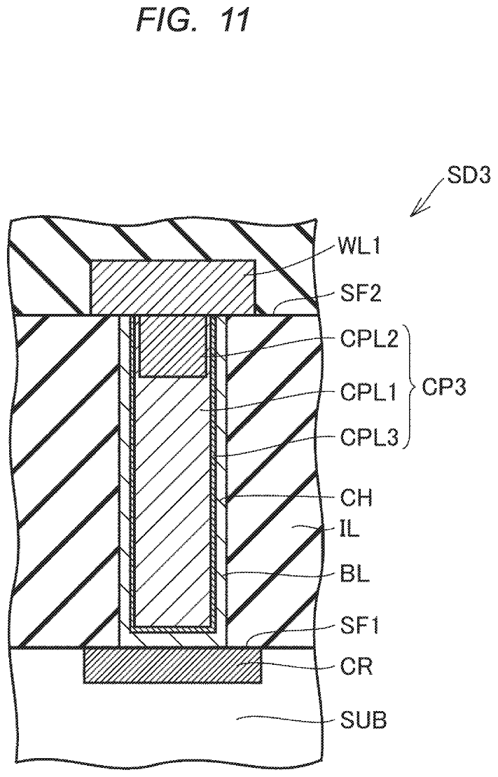

As shown in FIG. 11, a semiconductor device SD3 according to third embodiment has basically the same configuration as the semiconductor device SD according to first embodiment. The contact plug CP3 according to third embodiment differs from the contact plug CP1 of the semiconductor device SD in that the contact plug further includes a third layer CPL3 arranged so as to cover the inner circumferential surface of the contact hole CH.

Materials constituting the third layer CPL3 include Co. The third layer CPL3 has an outer circumferential surface that is in contact with the inner circumferential surface of the barrier layer BL, and an inner circumferential surface that is arranged on the other side of the barrier layer BL and faces inward in the contact hole CH. The inner circumferential surface of the third layer CPL3 is in contact with the first layer CPL1 of the contact plug CP3. The Co concentration of the third layer CPL3 is equal or more than the Co concentration of the first layer CPL1.

The manufacturing method of the semiconductor device SD3 basically has the same configuration as the manufacturing method of the semiconductor device SD according to the first embodiment. The manufacturing method of the semiconductor device SD3 differs from the manufacturing method of the semiconductor device SD in that the first film CPM1 is formed thicker than the manufacturing method of the semiconductor device SD. The thickness of the first film CPM1 is, for example, 5 nm or more.

A Cobalt (Co) in the first film CPM1 is diffused into the second film CPM2 by reflowing the second film CPM2 formed on the first film CPM1 by the reflow process. At this time, since the thickness of the first film CPM1 is thick, a part of the first film CPM1 located on the outer periphery of the contact hole CH remains. As a result, the first film CPM1 and the second film CPM2 are reconfigured into a first film CPM1 whose thickness has been reduced by the above described reflow as compared to before reflowing and a reflowed second film containing including the AlCo alloy containing Al and Co.

Thereafter, the semiconductor device SD3 is manufactured by processing in the same manner as the manufacturing method of the semiconductor device SD.

The contact plug CP3 includes the third layer CPL3 containing Co, but includes a second layer CPL2 similarly to the contact plug CP1. Therefore, the region containing Co on the third surface SF3 of the contact plug CP3 is narrower than the region containing Co in the contact plug not including the second layer CPL2. Therefore, the semiconductor device SD3 can exhibit the same effects as the semiconductor device SD.

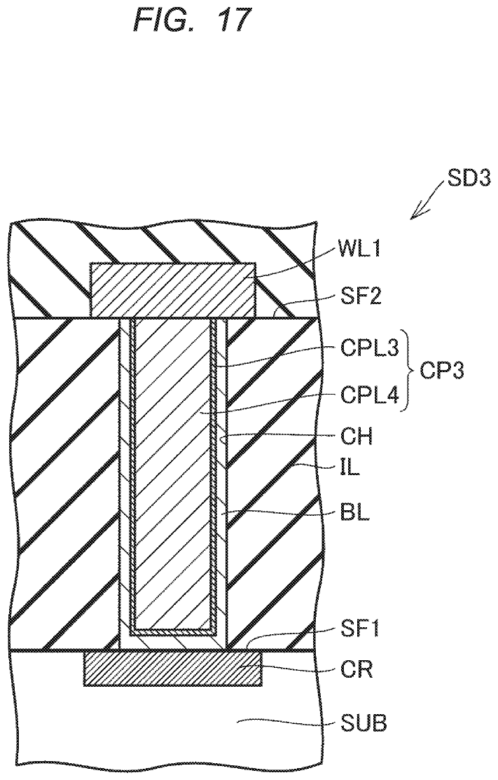

The semiconductor device SD3 may have basically the same configuration as the semiconductor device SD2, instead of the semiconductor device SD. That is, the contact plug CP2 of the semiconductor device SD2 may further include a third layer CPL3 arranged so as to cover the inner circumferential surface of the contact hole CH. From a different point of view, as shown in FIG. 17, the contact plug CP3 of the semiconductor device SD3 may not include the second layer CPL2. In this case, the contact plug CP3 is formed as a laminate of a fourth layer CPL4 containing AlCo formed by diffusing a part of Co in the first layer CPL1 and the third layer CPL3 into the second layer CPL2 after polishing by CMP, and the remaining third layer CPL3. The semiconductor device SD3 has the same effects as the semiconductor device SD2.

### Fourth Embodiment

A semiconductor device SD4 according to fourth embodiment has basically the same configuration as the semiconductor device SD according to first embodiment. The contact plug CP4 according to fourth embodiment differs from the contact plug CP1 of semiconductor device SD in that the second layer CPL2 contains Cu instead of Al.

Cu is a material polished by CMP and is less susceptible to electrochemical corrosion by CMP compared to Co. Furthermore, the specific resistance of Cu is less than the specific resistance of Tungsten (W), specifically less than 5.6×10−8 Ω·m. The second layer CPL2 may include alloys of Cu. The second layer CPL2 does not contain any of Al and Co constituting the first layer CPL1.

Also, in the semiconductor device SD4, since the materials constituting the second layer CPL2 do not contain Co, the semiconductor device SD4 can exhibit the same effects as the semiconductor device SD.

### Fifth Embodiment

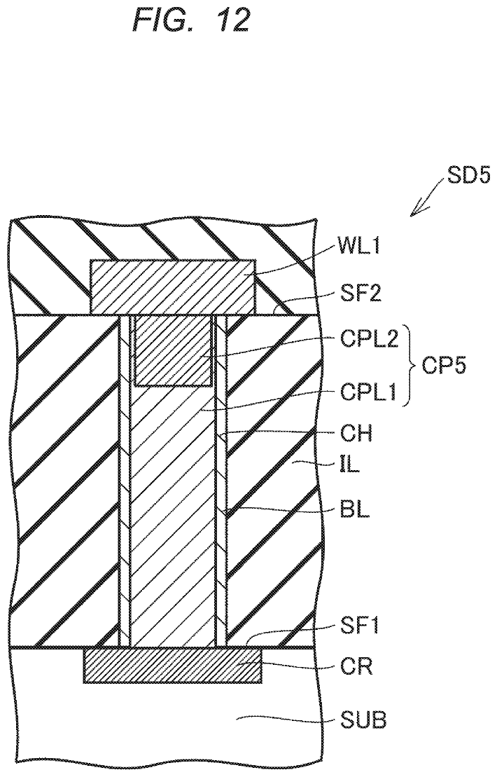

As shown in FIG. 12, a semiconductor device SD5 related to fifth embodiment has basically the same configuration as the semiconductor device SD related to first embodiment. The contact plug CP5 according to the fifth embodiment differs from the contact plug CP1 of the semiconductor device SD in that it contacts the conductive regions CR without intervention of the barrier layer BL.

The barrier layer BL is arranged so as to be in contact with the side wall of the contact hole CH. The barrier layer BL is opened on the bottom wall of the contact hole CH. The opening of the barrier layer BL is arranged on the central region of the bottom wall of the contact hole CH. The inner circumferential surface of the opening of the barrier layer BL is arranged, for example, so as to be continuous with the inner circumferential surface of the barrier layer BL.

The first layer CPL1 of the contact plug CP5 is arranged inside the inner circumferential surface of the barrier layer BL and the inner circumferential surface of the opening of the barrier layer BL in the contact hole CH. The first layer CPL1 of the contact plug CP5 is in direct contact with the conductive regions CRs without intervention of the barrier layer BL.

The manufacturing method of the semiconductor device SD5 has basically the same configuration as the manufacturing method of the semiconductor device SD. The manufacturing method of the semiconductor device SD5 differs from the manufacturing method of the semiconductor device SD in that a part of the barrier layer BL formed on the bottom wall of the contact hole CH is removed in the manufacturing process of forming the barrier layer BL.

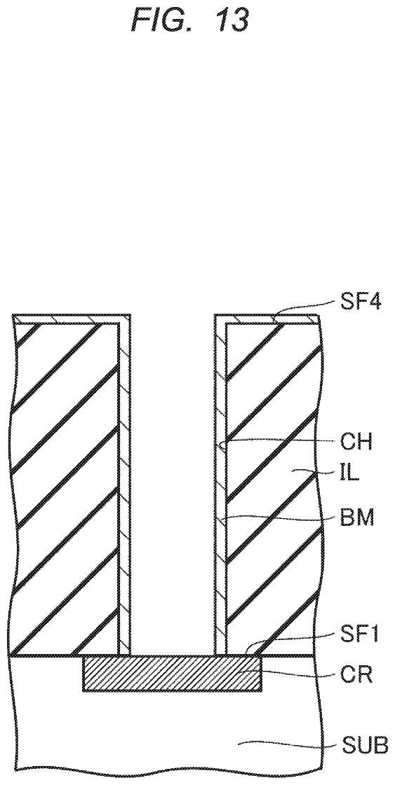

Specifically, as in the manufacturing method of semiconductor device SD, barrier layer BL is formed in contact hole CH so as to be in contact with side wall and bottom wall of the barrier layer BL. Next, as shown in FIG. 13, a part of the barrier layer BL arranged on the bottom wall of the contact hole CH is removed. A portion of the barrier layer BL is removed by, for example, applying a bias to the semiconductor substrate SUB and sputtering a portion of the barrier layer BL arranged on the bottom wall of the contact hole CH with argon (Ar) ions. Such sputtering can be performed by the sputtering device used for forming the TiN film, for example, when the TiN film is formed by sputtering. In this manner, the barrier layer BL shown in FIG. 12 is formed.

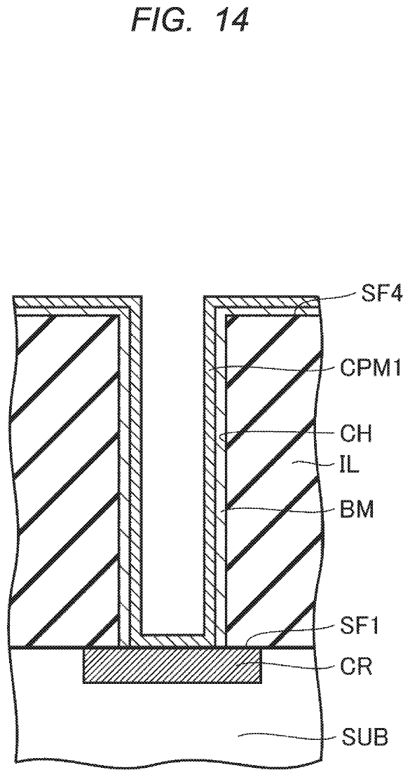

Next, as shown in FIG. 14, the first film CPM1 is arranged so as to be in contact with the conductive region CR. Thereafter, the semiconductor device SD5 is manufactured by processing in the same manner as the manufacturing method of the semiconductor device SD.

Since the semiconductor device SD5 has a configuration equivalent to that of the semiconductor device SD, effects equivalent to those of the semiconductor device SD can be obtained.

Further, in the manufacturing method of the semiconductor device SD5, as in the manufacturing method of the semiconductor device SD, when the first film CPM1, the second film CPM2, and the third film CPM3 are formed, fluorine-based gases such as WF6 are not used. Therefore, in the semiconductor device SD and the semiconductor device SD5, barrier layer for preventing so-called fluorine attack on the semiconductor substrate SUB is not required. Therefore, in the semiconductor device SD5, for example, a barrier layer BL is formed which covers the side wall of the contact hole CH and opens on the bottom wall of the contact hole CH from the viewpoint of preventing hydrogen from entering the contact plug CP5 from the insulating film IL, but further reducing the contact resistance as compared with the semiconductor device SD. That is, in the semiconductor device SD5, the barrier layer BL prevents hydrogen from entering the insulating layer IL into the contact plug CP5 similarly to the barrier layer BL in the semiconductor device SD, and the contact resistance is further reduced as compared with the semiconductor device SD.

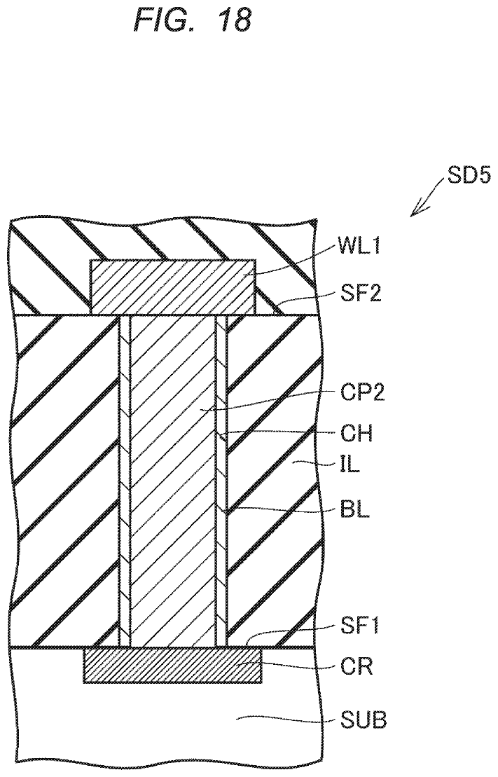

The semiconductor device SD5 may have basically the same configuration as the semiconductor device SD2, instead of the semiconductor device SD. That is, as shown in FIG. 18, the contact plug CP5 of the semiconductor device SD5 may not include the second layer CPL2. The semiconductor device SD5 has the same effects as the semiconductor device SD2.

### Modification

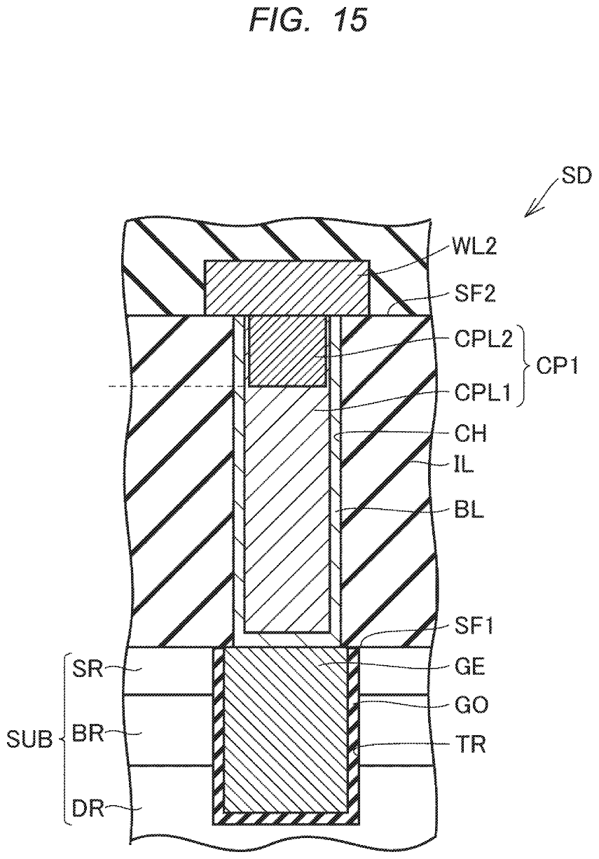

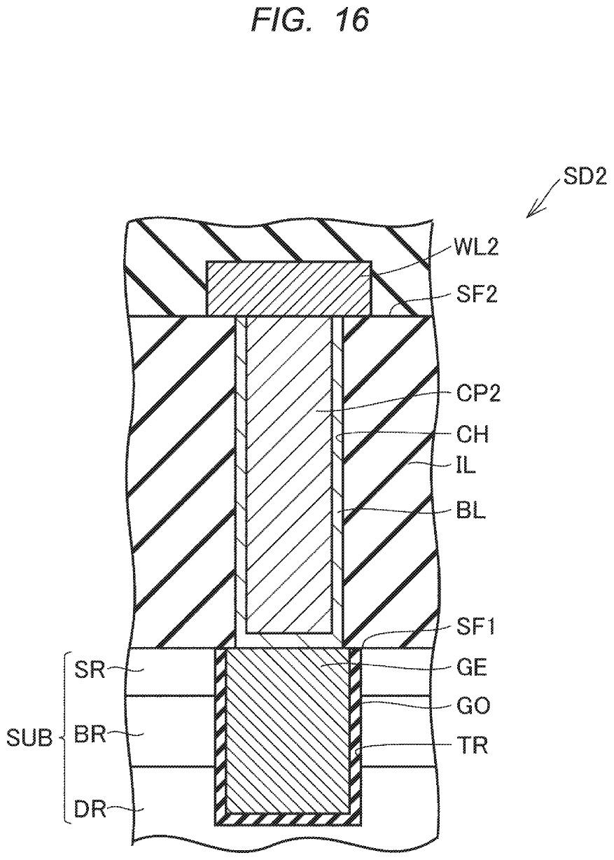

In the semiconductor devices SD, SD2, SD3, SD4 and SD5, the conductive portions to which the contact plugs CP1, CP2, CP3, and CP5 are electrically connected is configured as conductive region CR arranged in the semiconductor substrate SUB, but these are not limited thereto. As shown in FIGS. 15 and 16, the conductive portion according to each embodiment may be configured as, for example, a gate electrode GE. In this case, the contact plugs CP1, CP2, CP3 and CP5 are connected to the upper surface of the gate electrode GE and electrically connected to the gate electrode GE. Further, the contact plugs CP1, CP2, CP3 and CP5 are electrically connected to a wiring WL2. The gate electrode GE may be configured as, for example, a trench gate arranged in the trench TR. The trench TR is formed in a concave shape with respect to the first surface SF1. The trench TR penetrates the source region SR and the base region BR and reaches a drift region DR. A gate dielectric film GO is formed between the gate electrode GE and the side wall and the bottom wall of the trench TR.

The material constituting the gate electrode GE includes a metal material, for example, Al. In this case, the gate electrode may be formed by reflowing Al into the trench. In such a semiconductor device as well, the same effects as those of the semiconductor devices SD, SD2, SD3, SD4 and SD5 can be achieved by providing the same configurations as those of the semiconductor devices SD, SD2, SD3, SD4 and SD5 in the respective configurations other than the conductive portions.

Further, as shown in FIG. 15, when the conductive portion of the semiconductor device SD5 is formed as the gate electrode GE containing Al, the etching time in the manufacturing step of removing a part of the barrier layer BL arranged on the bottom wall of the contact hole CH is preferably set to be longer than the etching time required for removing a part of the barrier layer BL. An aluminum oxide film formed on the gate electrode is removed by over etching, and the contact resistance is further reduced.

The conductive portions may be, for example, electrodes arranged on semiconductor substrate SUB or wiring. That is, the through hole according to the embodiment may be configured as a via hole arranged between the electrode and the wiring or between the multilayer wirings, and the plug conductive layer may be configured as a plug for electrically connecting between the electrode and the wiring or between the multilayer wirings. Also in such a semiconductor device, the same effects as those of semiconductor devices SD, SD2, SD3, SD4 and SD5 can be achieved by providing the same configuration as that of semiconductor devices SD, SD2, SD3, SD4 and SD5 in the configurations other than the conductive portion, that is, the configurations of the insulating film IL, the contact hole CH, the contact plugs CP and the wiring WL1.

The semiconductor devices SD, SD2, SD3, SD4 and SD5 include a barrier layer BL arranged so as to cover at least the side wall of the contact hole CH, but may not include the barrier layer BL. As described above, since the contact plugs CP1, CP2, CP3 and CP5 are not formed using fluorine-based reactive gases, the barrier layer BL are not required to have a barrier performance for preventing so-called fluorine attack. Therefore, when the need for the barrier layer BL is low, the semiconductor devices SD, SD2, SD3, SD4 and SD5 may not include the barrier layer BL, even if other viewpoints such as ensuring reliability is considered. That is, the contact plugs CP1, CP2, CP3 and CP5 may be arranged so as to be in contact with the side wall and the bottom wall of the contact hole CH.

Although the invention made by the inventors has been specifically described above based on the embodiments, it is needless to say that the present invention is not limited to the embodiments and may be modified in various ways within a range not deviating from the scope thereof.

What is claimed is:

1. A semiconductor device, comprising:
a conductive region having a first surface arranged in or on a semiconductor substrate;
an insulating film arranged on the conductive region and providing a contact hole reaching to the first surface; and
a plug conductive layer arranged in the contact hole and connected to the conductive region, wherein
the plug conductive layer includes:
a first layer covering a side wall and a bottom wall of the contact hole; and
a second layer arranged on the first layer and located in an upper portion of the contact hole,
a material constituting the first layer includes aluminum and cobalt, and
a material constituting the second layer includes at least one of aluminum or copper.

2. The semiconductor device according to claim 1, wherein
a resistivity of materials constituting the second layer is less than 5.6×10−8 Ω·m.

3. The semiconductor device according to claim 1, wherein
in the upper surface of the plug conductive layer,
the second layer is arranged in a central region of the upper surface,
the first layer is arranged in a peripheral region surrounding the central region, and
an occupied area of the second layer is larger than an occupied area of the first layer.

4. The semiconductor device according to claim 1, wherein
the insulating film has a second surface, and
an aspect ratio defined by a depth of the contact hole to an opening dimension of the contact hole in the second surface is 5 or more.

5. The semiconductor device according to claim 1, wherein
a width of the first layer in a direction perpendicular to the second surface is larger than a width of the second layer in the perpendicular direction.

6. The semiconductor device according to claim 1, further comprising:
a third layer arranged outside of the first layer in the contact hole, wherein
a material constituting the third layer includes cobalt.

7. The semiconductor device according to claim 1, further comprising:
a barrier layer arranging so as to contact with the side wall in the contact hole, wherein
the plug conductive layer is arranged inside of the barrier layer in the contact hole and in contact with the conductive region.

8. The semiconductor device according to claim 1, wherein
the conductive region is an impurity area having a first conductivity type.

9. The semiconductor device according to claim 1, wherein
the conductive region is a gate electrode.

10. The semiconductor device according to claim 1, wherein
the material constituting the second layer does not include cobalt.

11. A semiconductor device, comprising:
a conductive region having a first surface and arranged in or on a semiconductor substrate;
an insulating film having a second surface, arranged on the conductive region and providing a contact hole reaching to the first surface;
a plug conductive layer arranged in the contact hole and connected to the conductive region; wherein
a material constituting the plug conductive layer includes aluminum and cobalt,
an aspect ratio defined by a depth of the contact hole to an opening dimension of the contact hole in the second surface is 5 or more, and
the plug conductive layer is densely arranged in the contact hole.

12. The semiconductor device according to claim 11, further comprising:
a second layer arranged so as to cover an inner circumferential surface of the contact hole, wherein
a material constituting the second layer includes cobalt.

13. The semiconductor device according to claim 11, further comprising:
a barrier layer arranging so as to contact with a side wall of the contact hole, wherein
the plug conductive layer is arranged inside of the barrier layer in the contact hole and in contact with the conductive region.

14. The semiconductor device according to claim 11, wherein
the conductive region is an impurity area having a first conductivity type.

15. The semiconductor device according to claim 11, wherein
the conductive region is a gate electrode

16. A method of manufacturing a semiconductor device, comprising the steps of:
preparing a semiconductor substrate including a conductive region;
forming an insulating film on the conductive region;
forming a contact hole reaching to the conductive region; and
forming a plug conductive layer connected to the conductive region in the contact hole, wherein the step of forming the plug conductive layer includes the steps of:
forming a first film including cobalt on at least a side wall or a bottom wall of the contact hole;
forming a second film including aluminum on the first film;
reflowing the second film;
forming a third film including at least one of aluminum or copper on a reflowed second film; and
polishing the third film, the reflowed second film and the first film at least until exposing an upper surface of the insulating film.

17. The method of manufacturing a semiconductor device according to the claim 16, wherein
a thickness of the first film is 3 nm or more.

18. The method of manufacturing a semiconductor device according to the claim 16, further comprising the step of:
after the step of forming the plug conductive layer, heating the plug conductive layer to diffuse cobalt in the plug conductive layer.

19. The method of manufacturing a semiconductor device according to the claim 16, further comprising the step of:
after the step of forming the contact hole, before the step of forming the plug conductive layer, forming a barrier layer arranged so as to contact with a side wall of the contact hole, wherein
in the step of forming the plug conductive layer, the plug conductive layer is arranged inside of the barrier layer in the contact hole and in contact with the conductive region.
